(19) United States
(12) Patent Application Publication
(10) Pub. No.: US 2024/0304484 A1
(43) Pub. Date: Sep. 12, 2024

(54) TRANSFER ROBOT AND STOCKER SYSTEM INCLUDING THE SAME

(71) Applicant: SAMSUNG ELECTRONICS CO. LTD., SUWON-SI (KR)

(72) Inventors: Hyeon Uk KIM, SUWON-SI (KR); Kyoung Soo KIM, SUWON-SI (KR); Kun Jin RYU, SUWON-SI (KR); Gyeong Dam BAEK, SUWON-SI (KR); Seung Hyuk BAEK, SUWON-SI (KR); Dong Chan SEO, SUWON-SI (KR); Hu Jong LEE, SUWON-SI (KR); Jae Hyuk CHA, SUWON-SI (KR); Ji Won YOON, Suwon-si, (KR); Sun Oh KIM, Hwaseong-si (KR); Kyeong Jun MIN, SUWON-SI (KR); Ji Wook KWON, Hanam-si (KR); Seung Seok HA, Seoul (KR); Gil Do KIM, Anseong-si (KR)

(73) Assignee: SEMES CO., LTD., Cheonan-si (KR)

(21) Appl. No.: 18/525,803

(22) Filed: Nov. 30, 2023

(30) Foreign Application Priority Data
Mar. 9, 2023 (KR) 10-2023-0030958

(51) Int. Cl. H01L 21/677; H01L 21/67

(52) U.S. Cl. CPC H01L 21/6773; H01L 21/67259; B25J 11/0095

(57) ABSTRACT

A stocker system including a stocker apparatus, a transfer robot including a sensing module and a robot arm, a manual port of the stocker apparatus, and a controller in communication with the transfer robot, wherein the controller communicates with the sensing module to determine that a container is transferrable by the robot arm between the manual port of the stocker apparatus and the transfer robot.

### CROSS-REFERENCE TO RELATED APPLICATION

This application claims priority under 35 U.S.C. § 119 to Korean Patent Application No. 10-2023-0030958, filed on Mar. 9, 2023, in the Korean Intellectual Property Office, the contents of which are herein incorporated by reference it their entirety.

### BACKGROUND

### Technical Field

The present disclosure relates to a semiconductor production line, and more particularly, to a transfer robot and a stocker system including the same.

### Discussion of Related Art

Semiconductor production lines are increasingly relying on automation systems. These automation systems may perform certain tasks within a semiconductor manufacturing factory. As a part of this trend, containers may be used to carry a plurality of semiconductor substrates within the semiconductor manufacturing factory, and the containers may be moved within the semiconductor manufacturing factory by, for example, an overhead hoist transport (OHT).

In some cases, a container may need to be stored for a period of time during a process of manufacturing a semiconductor device. A stocker apparatus may be used to hold a plurality of containers during the storage period.

### SUMMARY

An object of the present disclosure is to provide a transfer robot that may determine whether a stocker apparatus is prepared to load or unload a container, and a stocker system including the same.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a stocker system comprising: a stocker apparatus; a transfer robot including a sensing module and a robot arm; a manual port of the stocker apparatus; and a controller in communication with the transfer robot, wherein the controller communicates with the sensing module to determine that a container is transferrable by the robot arm between the manual port of the stocker apparatus and the transfer robot.

According to another aspect of the present disclosure, a transfer robot operating in a semiconductor manufacturing factory, the transfer robot comprising: a frame; a robot arm disposed in the frame and extendable to the outside of the frame; and a lamp sensing module outputting a signal indicative of whether a stocker apparatus is prepared to transfer a container.

According to another aspect of the present disclosure, a stocker system comprising: a stocker apparatus storing a container in which a plurality of substrates are accommodated; a transfer robot including a sensing module and a robot arm; a manual port of the stocker apparatus; and a controller controlling the stocker apparatus and the transfer robot, wherein the controller communicates with the sensing module to determine a state of the stocker apparatus, the manual port includes a lamp indicating the state of the stocker apparatus, the sensing module senses the lamp, and the robot arm transfers the container between the stocker apparatus and the transfer robot depending on the state of the stocker apparatus.

### BRIEF DESCRIPTION OF THE DRAWINGS

These and/or other aspects will become apparent and more readily appreciated from the following description of embodiments, taken in conjunction with the accompanying drawings in which:

FIG. 1 is a block diagram illustrating a stocker system.

FIG. 2 is a first exemplary view illustrating a transfer robot of a stocker system in block units.

FIG. 3 is a second exemplary view illustrating a transfer robot of a stocker system in block units.

FIG. 4 is an exemplary view schematically illustrating a structure of a manual port of a stocker system.

FIG. 5 is an exemplary view illustrating a robot arm of a transfer robot.

FIG. 6 is a first exemplary view illustrating a container sensing module of a transfer robot.

FIG. 7 is a second exemplary view illustrating a container sensing module of a transfer robot.

FIG. 8 is a first exemplary view illustrating a lamp of a manual port.

FIG. 9 is a second exemplary view illustrating a lamp of a manual port.

FIG. 10 is an exemplary view illustrating a lamp sensing module of a transfer robot.

FIG. 11 is a first exemplary view illustrating a rotational motion of the lamp sensing module.

FIG. 12 is a second exemplary view illustrating a rotational motion of the lamp sensing module.

FIG. 13 is a first exemplary view illustrating a rotational motion and a straight motion of a lamp sensing module.

FIG. 14 is a second exemplary view illustrating a rotational motion and a straight motion of the lamp sensing module.

### DETAILED DESCRIPTION

Hereinafter, exemplary embodiments of the present disclosure will be described in detail with reference to the accompanying drawings. The same components in the drawings will be denoted by the same reference numerals, and overlapping descriptions thereof may be omitted.

The present disclosure relates to a transfer robot capable of interacting with a stocker apparatus, and more particularly to a transfer robot configured to carry a container, load the container into the stocker apparatus, and unload the container from the stocker apparatus. The container may house one or more semiconductor substrates. A stocker system of the present disclosure, which may include the transfer robot and the stocker apparatus, may serve to determine whether the container may be loaded into, or unloaded from, the stocker apparatus. Hereinafter, the present disclosure will be described in detail with reference to the drawings.

FIG. 1 is a block diagram illustrating a stocker system. Referring to FIG. 1, a stocker system 100 may include a manual port 110, a transfer robot 120, a stocker apparatus 130, and a controller 140.

The stocker system 100 may transport and store a container in which a plurality of substrates are accommodated. The stocker system 100 may load the container into the stocker apparatus 130 in a first mode. The stocker system 100 may load the container into the stocker apparatus 130 and store the substrate in the stocker apparatus 130. The stocker system 100 may unload the container from the stocker apparatus 130 in a second mode. After unloading the container stored in the stocker apparatus 130, the stocker system 100 may transfer the container to a destination by using the transfer robot 120.

The container may have a front open unified pod (FOUP) structure. For example, the container may load and accommodate a plurality of substrates, e.g., silicon wafers, in the FOUP. The container may secure the plurality of substrates in a controlled environment, and may allow the plurality of substrates to be transferred between different portions of a semiconductor manufacturing factory for processing or measurement.

The manual port 110 may be disposed on a front surface of the stocker apparatus 130. The manual port 110 may be provided as a portion of the stocker apparatus 130, but is not limited thereto. The manual port 110 may be provided as a separate component, apart from the stocker apparatus 130.

The manual port 110 may receive the container from the transfer robot 120 in the first mode. The manual port 110 may provide the container provided from the transfer robot 120 to the stocker apparatus 130 in the first mode. The manual port 110 may operate as an interface for transferring the container from the transfer robot 120 to the stocker apparatus 130 when loading the container into the stocker apparatus 130.

The manual port 110 may receive the container from the stocker apparatus 130 in the second mode. The manual port 110 may provide the container provided from the stocker apparatus 130 to the transfer robot 120 in the second mode. The manual port 110 may operate as an interface for transferring the container from the stocker apparatus 130 to the transfer robot 120 when unloading the container from the stocker apparatus 130.

The transfer robot 120 may carry the container. The transfer robot 120 may move to a destination and transfer the container. The transfer robot 120 may move among destinations in the semiconductor manufacturing factory. For example, the transfer robot 120 may freely move in the semiconductor manufacturing factory without being fixed in its position.

The transfer robot 120 may be temporarily aligned at the manual port 110. The manual port 110 may be a destination at which the container may be exchanged under the control of the controller 140. The transfer robot 120 may be aligned with the manual port 110. The transfer robot 120 aligned with the manual port 110 may exchange the container with the manual port 110.

The transfer robot 120 may provide the container to the manual port 110 in the first mode. That is, the transfer robot 120 may transfer the container to the manual port 110 when loading the container into the stocker apparatus 130. The transfer robot 120 may receive the container from the manual port 110 in the second mode. That is, the transfer robot 120 may receive the container from the manual port 110 when unloading the container from the stocker apparatus 130.

The stocker apparatus 130 may store the container. The stocker apparatus 130 may accommodate and store the container. For example, the container may be loaded onto a shelf provided in the stocker apparatus 130. The stocker apparatus 130 may receive the container through the manual port 110. The stocker apparatus 130 may store the container by stacking the container. The stocker apparatus 130 may unload the container stored to the outside through the manual port 110.

In FIG. 1, the stocker apparatus 130 may be provided with the container through the manual port 110, but embodiments are not limited thereto. For example, the stocker apparatus 130 may be provided with the container from an overhead hoist transport (OHT). The OHT may ascend or descend the container by using a hoist. Alternatively, the stocker apparatus 130 may be provided with the container from an overhead shuttle (OHS). The OHS may slide the container in a horizontal direction.

The controller 140 may control components of the stocker system 100, such as the manual port 110, the transfer robot 120, and the stocker apparatus 130.

The controller 140 may control movement of the transfer robot 120. The controller 140 may control transportation of the container by the transfer robot 120. For example, the controller 140 may control a movement path of the transfer robot 120 in accordance with a position of the manual port 110 provided with the container from the transfer robot 120.

The controller 140 may control the stocker apparatus 130 to store the container. For example, the controller 140 may control the stocker apparatus 130 to load the container inside the stocker apparatus 130. For another example, the controller 140 may control the stocker apparatus 130 to provide the container to the outside.

The controller 140 may include a process controller including a microprocessor (computer) for controlling the stocker system 100, a user interface to manage the stocker system 100, a display for visualizing and displaying an operating situation of the stocker system 100, and a memory for storing a control program for executing a process, which may be executed in the stocker system 100, under the control of the process controller, or a program of instructions for executing a process in accordance with various data and processing conditions. The user interface may include, for example, a keyboard for inputting commands to the stocker system 100. The user interface and the memory may be connected to the process controller. The program of instructions may be stored in a memory medium of the memory. The memory medium may be, for example, a hard disk, a portable disk such as a CD-ROM or a DVD, or a semiconductor memory such as a flash memory.

The transfer robot 120 may detect a state of the manual port 110 and a state of the stocker apparatus 130. to the transfer robot 120 may determine whether the stocker apparatus 130 may load or unload the container. For example, the transfer robot 120 may be constructed as a manipulator integrated mobile robot, and may be equipped with a vision sensor. Hereinafter, such a transfer robot will be described.

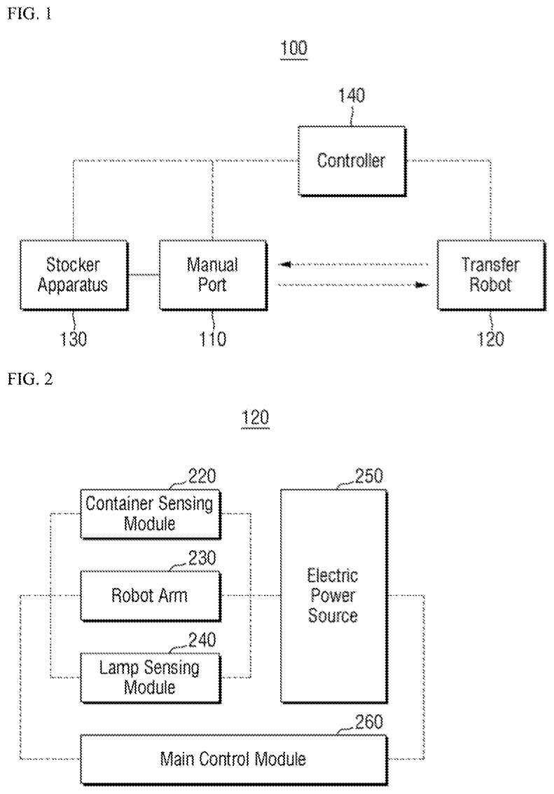

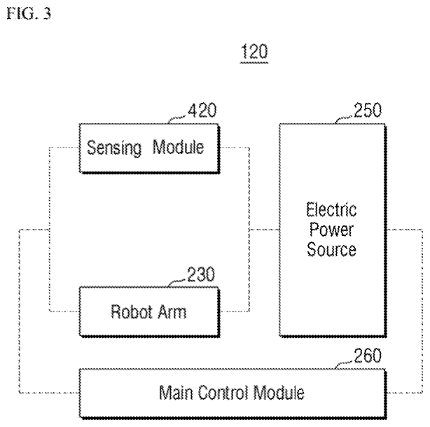

FIG. 2 is an exemplary view illustrating a transfer robot of a stocker system in block units. In addition, FIG. 3 is a second exemplary view illustrating a transfer robot of a stocker system in block units.

Referring to FIG. 3, the transfer robot 120 may include a sensing module 420, a robot arm 230, an electric power source 250, and a main control module 260. Referring to FIG. 2, the transfer robot 120 may include a container sensing module 220, the robot arm 230, a lamp sensing module 240, the electric power source 250, and the main control module 260.

The sensing module 420 may be provided by integrating the container sensing module 220 with the lamp sensing module 240. That is, the sensing module 420 may perform both the role of the container sensing module 220 and the role of the lamp sensing module 240. The sensing module 420 may be provided as, for example, a vision sensor. Hereinafter, for convenience of description, the role of the container sensing module 220 and the role of the lamp sensing module 240 will be separately described.

The container sensing module 220 may sense the presence or absence of the container at the manual port 110. The container sensing module 220 may sense the presence or absence of the container at the manual port 110 in various manners in accordance with an embodiment. For example, the container sensing module 220 may sense the presence or absence of the container at the manual port 110 by using a camera sensor. For another example, the container sensing module 220 may sense the presence or absence of the container at the manual port 110 by using an optical sensor.

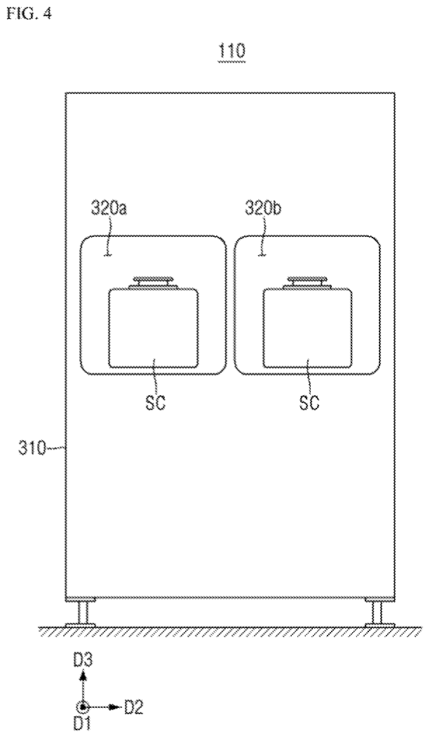

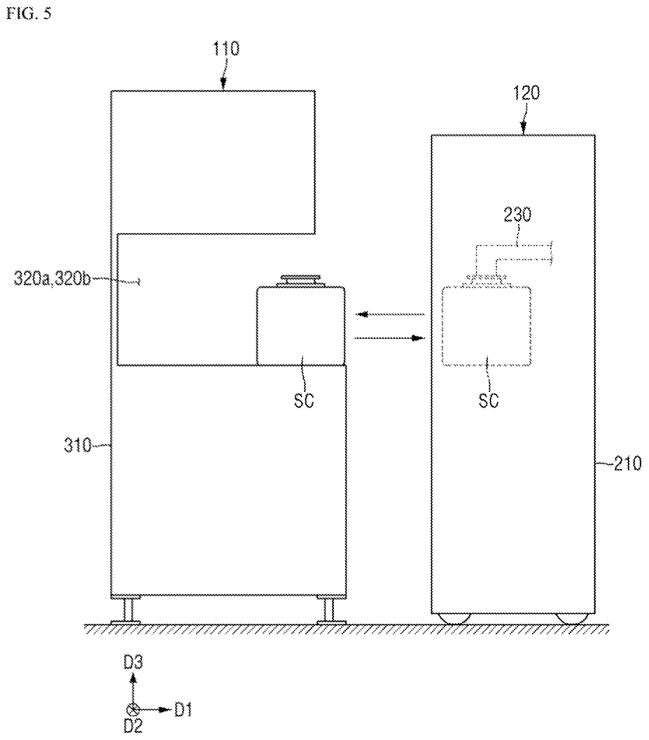

Referring to FIG. 4, the manual port 110 may include a plurality of openings in a second frame 310. The manual port 110 may exchange the container with the transfer robot 120 through the plurality of openings. For example, the manual port 110 may include a first opening 320a and a second opening 320b in the second frame 310. FIG. 4 is an exemplary view schematically illustrating a structure of a manual port of a stocker system.

When the manual port 110 includes the first opening 320a and the second opening 320b, the first opening 320a may be used as an opening for loading a container SC into the stocker apparatus 130, and the second opening 320b may be used as an opening for unloading the container SC from the stocker apparatus 130, but the present disclosure is not limited thereto. The first opening 320a and the second opening 320b may be used as openings for loading the container SC into the stocker apparatus 130, and the first opening 320a and the second opening 320b may be used as openings for unloading the container SC from the stocker apparatus 130.

The first opening 320a and the second opening 320b of the manual port 110 may be arranged in a horizontal direction, that is, in a second direction D2, but the present disclosure is not limited thereto. The first opening 320a and the second opening 320b of the manual port 110 may be arranged in a vertical direction, that is, a third direction D3. Alternatively, the first opening 320a and the second opening 320b of the manual port 110 may be arranged in a diagonal direction. In the above description, the second direction D2 extends in the horizontal direction with respect to a bottom surface in the semiconductor manufacturing factory, and the third direction D3 extends in the vertical direction with respect to the bottom surface in the semiconductor manufacturing factory.

The manual port 110 may include a single opening in the second frame 310 without being limited to including a plurality of openings in the second frame 310. For example, the first opening 320a and the second opening 320b may be combined into a single opening.

The container sensing module 220 may sense the presence or absence of the container SC at the manual port 110 by recognizing the container SC exposed to the outside through the first opening 320a or the second opening 320b of the manual port 110. The container sensing module 220 may be disposed on a front surface of the transfer robot 120 to recognize the container SC inside the first opening 320a or the second opening 320b of the manual port 110.

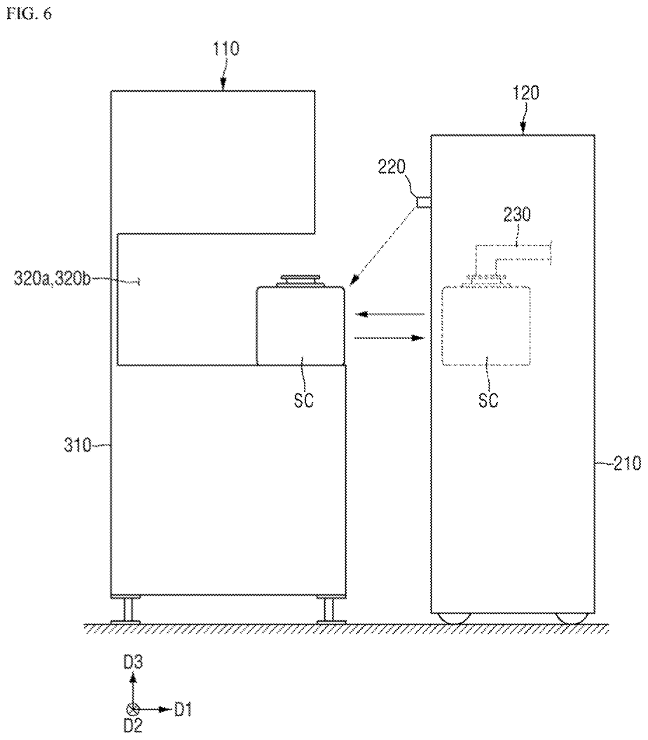

Referring to FIG. 5, the transfer robot 120 may transfer the container SC to the first opening 320a or the second opening 320b of the manual port 110 by using the robot arm 230. In addition, the transfer robot 120 may receive the container SC from the first opening 320a or the second opening 320b of the manual port 110 by using the robot arm 230.

The robot arm 230 may be positioned inside the first frame 210 of the transfer robot 120. When the robot arm 230 transfers the container SC to the manual port 110, or receives the container SC from the manual port 110, the robot arm 230 may protrude to the outside of the first frame 210.

The robot arm 230 may move in a first direction D1 to transfer the container SC to the manual port 110. The robot arm 230 may move in the first direction D1 to receive the container SC from the manual port 110. For this operation of the robot arm 230, at least one of the first opening 320a or the second opening 320b of the manual port 110 and the robot arm 230 may be disposed at a same level in the third direction D3. FIG. 5 is an exemplary view illustrating a robot arm of a transfer robot.

The container sensing module 220 may be disposed on the front surface of the transfer robot 120. The container sensing module 220 may sense whether the container SC exists in one of the first opening 320a or the second opening 320b of the manual port 110.

As illustrated in FIG. 5, the transfer robot 120 may be a cart type robot, configured to move about a floor of a factory. For example, the transfer robot 120 may include wheels and drive motors for moving about the floor of the factory, but is not limited thereto. For example, the transfer robot 120 may be a tracked type robot. The transfer robot 120 may include sensors for navigating the factory, for example, to a designated location at the manual port 110 the stocker apparatus 130. These sensors may be, for example, optical or radar based. Additional sensors may detect landmarks in the factory or may be based on a global positioning system using satellites.

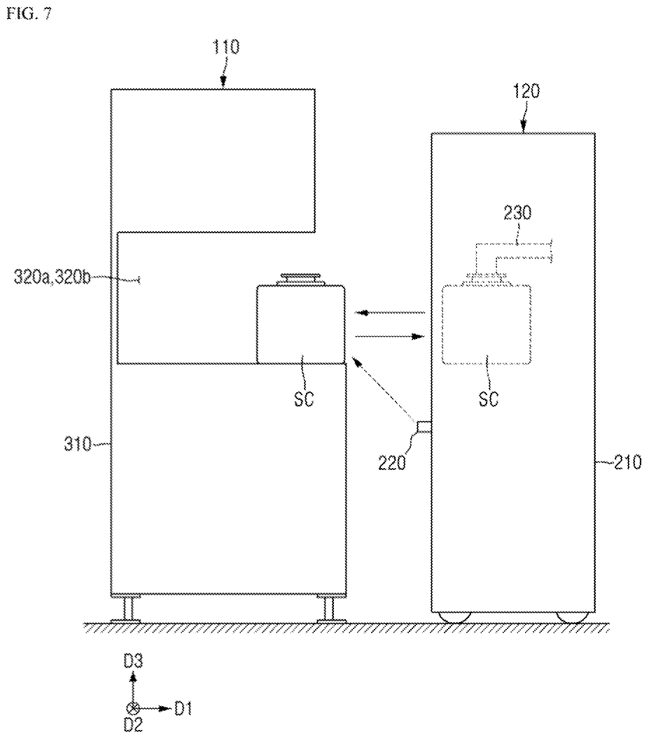

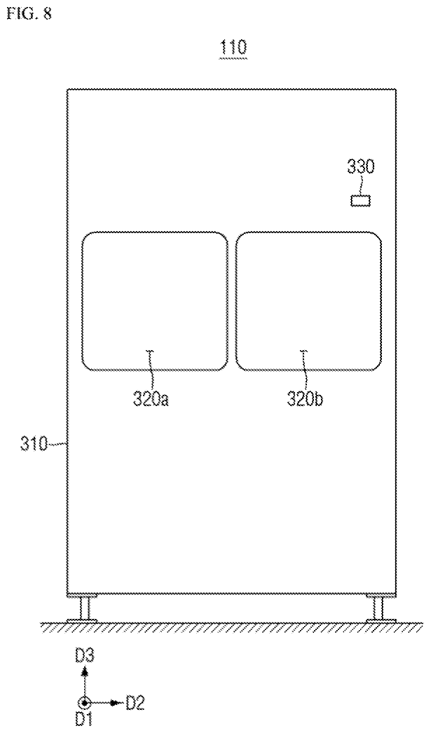

A container sensing operation of the container sensing module 220 and a container transfer operation of the robot arm 230 may need to be independent of each other. To this end, referring to FIG. 6, the container sensing module 220 may be disposed at a higher level than the robot arm 230. Alternatively, referring to FIG. 7, the container sensing module 220 may be disposed at a lower level than the robot arm 230, but is not limited thereto. For example, the container sensing module 220 may be disposed at the same level as the robot arm 230. When the container sensing module 220 is disposed at the same level as the robot arm 230, the container sensing operation of the container sensing module 220 may be performed after the container transfer operation of the robot arm 230 is completed. FIG. 6 is a first exemplary view illustrating a container sensing module of a transfer robot. In addition, FIG. 7 is a second exemplary view illustrating a container sensing module of a transfer robot.

When the container sensing module 220 is disposed at a higher level than the robot arm 230, or is disposed at a lower level than the robot arm 230, the container sensing operation of the container sensing module 220 may be performed simultaneously with the container transfer operation of the robot arm 230. For example, the container sensing operation of the container sensing module 220 may be performed in real time while the container transfer operation of the robot arm 230 is performed.

When the container sensing operation of the container sensing module 220 is performed simultaneously with the container transfer operation of the robot arm 230, the container sensing module 220 may sense whether the robot arm 230 properly transfers the container SC to the first opening 320a or the second opening 320b of the manual port 110. In addition, the container sensing module 220 may sense whether the robot arm 230 correctly receives the container SC from the first opening 320a or the second opening 320b of the manual port 110, but is not limited thereto. For example, the container sensing operation of the container sensing module 220 may be performed after the container transfer operation of the robot arm 230 is completed.

Referring again to FIG. 2 and FIG. 3, the lamp sensing module 240 may sense a lamp installed in the manual port 110. The lamp sensing module 240 may sense light emitted from the lamp installed in the manual port 110.

The lamp sensing module 240 may provide an electrical signal to the controller 140, the electrical signal including information about light emitted from the lamp. The controller 140 may determine a mode of the stocker apparatus 130 using a sensor signal provided from the lamp sensing module 240. The controller 140 may control the operation of the robot arm 230 in accordance with a mode determined using the electrical signal provided by the lamp sensing module 240.

A lamp for displaying the state of the stocker apparatus 130 may be installed in the manual port 110. The lamp for displaying the state of the stocker apparatus 130 may be installed in front of the manual port 110. For example, the lamp sensing module 240 may be equipped with a vision sensor, and may recognize the lamp by using the vision sensor. The controller 140 may determine whether a transfer operation of the container SC may be performed in connection with the manual port 110 using the lamp recognition result of the lamp sensing module 240. The transfer operation may be a loading operation or an unloading operation.

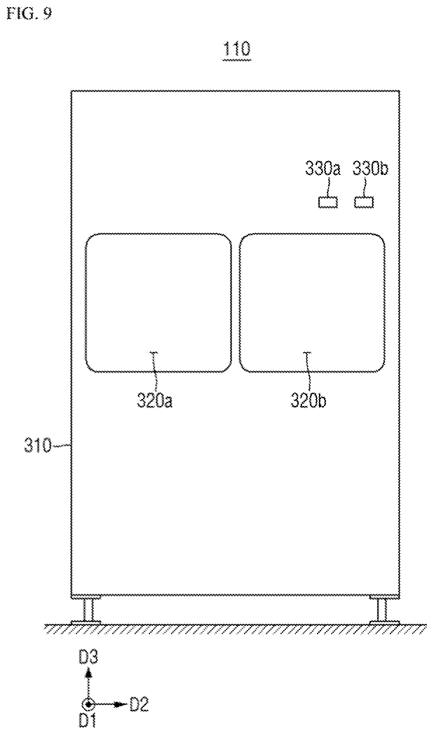

Referring to FIG. 8, the manual port 110 includes a lamp 330. The lamp 330 may be visible to a front surface of the manual port 110. The lamp 330 may be disposed on the front surface of the manual port 110. The lamp 330 may be disposed at a higher level than the first opening 320a and the second opening 320b, but is not limited thereto. The lamp 330 may be disposed at a lower level than the first opening 320a and the second opening 320b. Alternatively, the lamp 330 may be disposed at the same level as the first opening 320a and the second opening 320b.

When the lamp 330 is disposed at the same level as the first opening 320a and the second opening 320b, the lamp 330 may be disposed between the first opening 320a and the second opening 320b. Alternatively, the lamp 330 may be disposed outside the first opening 320a. Alternatively, the lamp 330 may be disposed outside the second opening 320b. FIG. 8 is a first exemplary view illustrating a lamp of a manual port.

The lamp 330 may indicate an operational state of the stocker apparatus 130 in accordance with a color that is displayed. For example, when the lamp 330 emits light of a first color, it may indicate a first mode in which the stocker apparatus 130 is prepared to load the container SC. Also, when the lamp 330 emits light of a second color, it may indicate a second mode in which the stocker apparatus 130 is prepared to unload the container SC. In addition, when the lamp 330 emits light of a third color, it may indicate a third mode in which the stocker apparatus 130 may not be prepared to transfer the container SC. The transfer may be a loading operation or an unloading operation.

However, the present disclosure is not limited to the above example. The lamp 330 may also indicate the operational state of the stocker apparatus 130 in accordance with switching on/off. For example, when the lamp 330 is turned on, it may indicate the first mode in which the stocker apparatus 130 is prepared to load the container SC. Also, when the lamp 330 flashes, blinks, or pulses, it may indicate the second mode in which the stocker apparatus 130 is prepared to unload the container SC. In addition, when the lamp 330 is turned off, it may indicate the third mode in which the stocker apparatus 130 may not be prepared to transfer the container SC. The transfer may be a loading operation or an unloading operation.

The container SC may be transferrable between the stocker apparatus 130 and the transfer robot 120 in a case where the container SC is present in the manual port 110 or in a case where the manual port 110 is clear of another container SC. In the case where the container SC is present in the manual port 110, the container SC may be unloaded by the robot arm 230 of the transfer robot 120. In the case where the manual port 110 is clear of another container SC, the container SC may be loaded into the manual port 110 by the robot arm 230 of the transfer robot 120.

The controller 140 may determine that the stocker apparatus 130 cannot load or unload the container SC when the state of the stocker apparatus 130 is in the first mode or the second mode. When the state of the stocker apparatus 130 is in the third mode, the controller 140 may determine that the stocker apparatus 130 may be prepared to transfer the container SC.

The lamp 330 may indicate whether the stocker apparatus 130 may be prepared to load or unload the container SC in accordance with a color that is displayed. For example, when the lamp 330 emits light of a fourth color, it may indicate a fourth mode in which the stocker apparatus 130 may be prepared to load or unload the container SC. When the lamp 330 emits light of a fifth color, it may indicate a fifth mode in which the stocker apparatus 130 may not be prepared to load or unload the container SC.

However, the present disclosure is not limited to the above examples, and the lamp 330 may indicate whether or not the container SC may be loaded and unloaded, in accordance with being on or off. For example, when the lamp 330 is turned on, it may indicate the fourth mode in which the stocker apparatus 130 may be prepared to load or unload the container SC. When the lamp 330 is turned off, it may indicate the fifth mode in which the stocker apparatus 130 may not be prepared to transfer the container SC.

The lamp 330 may indicate an operational state of the stocker apparatus 130 in accordance with a pattern that is displayed. For example, when the lamp 330 is turned on and off in a first pattern (e.g., a slow blink), it may indicate the first mode in which the stocker apparatus 130 is prepared to load the container SC. Also, when the lamp 330 is turned on and off in a second pattern (e.g., a fast blink), it may indicate the second mode in which the stocker apparatus 130 is prepared to unload the container SC. In addition, when the lamp 330 has a solid pattern (e.g., is either on or off), it may indicate the third mode in which the stocker apparatus 130 may not be available to transfer the container SC.

In order to identify the mode of the stocker apparatus 130, a plurality of lamps 330 may be provided in the manual port 110. Referring to FIG. 9, the manual port 110 may include more than one lamp. For example, the manual port 110 may include two lamps, such as a first lamp 330a and a second lamp 330b, but the present disclosure is not limited thereto. Three or more lamps may be provided in the manual port 110. FIG. 9 is a second exemplary view illustrating a lamp of a manual port.

When the first lamp 330a and the second lamp 330b are provided in the manual port 110, the first lamp 330a may indicate the first mode, the second mode, or the third mode of the stocker apparatus 130, and the second lamp 330b may indicate the fourth mode and the fifth mode of the stocker apparatus 130. That is, the first lamp 330a may indicate the operational state of the stocker apparatus 130, and the second lamp 330b may indicate whether the stocker apparatus 130 is prepared to load or unload the container SC, but the present disclosure is not limited thereto. The first lamp 330a may indicate the fourth mode or the fifth mode of the stocker apparatus 130, and the second lamp 330b may indicate the first mode, the second mode, or the third mode of the stocker apparatus 130.

The first lamp 330a and the second lamp 330b may be disposed to be spaced apart from each other at a predetermined distance on the manual port 110. The first lamp 330a and the second lamp 330b may be disposed at the same level on the manual port 110. For example, both the first lamp 330a and the second lamp 330b may be disposed at a higher level than the first opening 320a and the second opening 320b of the manual port 110.

However, the present disclosure is not limited to the above example, and the first lamp 330a and the second lamp 330b may be disposed at different levels on the manual port 110. For example, the first lamp 330a may be disposed at a higher level than the first opening 320a and the second opening 320b, and the second lamp 330b may be disposed at a lower level than the first opening 320a and the second opening 320b.

The first lamp 330a may display any of the first mode to the fifth mode of the stocker apparatus 130. The second lamp 330b may display any of the first mode to the fifth mode of the stocker apparatus 130. The first lamp 330a or the second lamp 330b may disposed any of the first mode to the fifth mode depending on an operational state of the manual port 110.

The first lamp 330a and the second lamp 330b may indicate a current mode of the stocker apparatus 130. For example, the first lamp 330a and the second lamp 330b may indicate the current mode by using color. The color indicating the first mode, the color indicating the second mode, the color indicating the third mode, the color indicating the fourth mode, and the color displaying the fifth mode may be all different from one another.

The first lamp 330a and the second lamp 330b may indicate a current mode of the stocker apparatus 130 by switching on/off. In this case, the first lamp 330a may indicate any one mode of the first mode to the third mode and the second lamp 330b may indicate any one mode of the fourth mode and the fifth mode. Alternatively, at least one of the first lamp 330a or the second lamp 330b may sequentially display one mode of the fourth mode and the fifth mode, and display any one mode of the first mode to the third mode.

When any one of the first mode to the third mode is indicated by the first lamp 330a and then the mode of any one of the fourth mode and the fifth mode is indicated by the second lamp 330b, the first lamp 330a and the second lamp 330b may vary the time for indicating each mode and the time therebetween. For example, the first lamp 330a and the second lamp 330b may indicate any one mode of the first mode to the third mode for a first time, and then may be repeatedly turned on, flashed, and turned off during a second time, and then may indicate any one mode of the fourth mode and the fifth mode for a third time. A period of the third time may be the same as a period of the first time, but is not limited thereto, and the period of the third time may be different from the period of the first time.

When any one of the fourth mode and the fifth mode is indicated by the second lamp 330b and then any one mode of the first mode to the third mode is indicated by the first lamp 330a, the first lamp 330a and the second lamp 330b may vary the time for displaying each mode and the time therebetween. For example, the first lamp 330a and the second lamp 330b may display any one mode of the fourth mode and the fifth mode for a first time, and then may be repeatedly turned on, flashed, and turned off for a second time, and then may display any one mode of the first mode to the third mode for a third time. A period of the third time may be the same as a period of the first time, but is not limited thereto, and the period of the third time may be different from the period of the first time.

The first lamp 330a and the second lamp 330b may distinguish and indicate the first mode to the fifth mode of the stocker apparatus 130 in the same manner, but the present disclosure is not limited thereto. The first lamp 330a and the second lamp 330b may distinguish and indicate the first mode to the fifth mode of the stocker apparatus 130 in different ways.

The first lamp 330a indicates the first mode to the third mode of the stocker apparatus 130, the second lamp 330b indicates the fourth mode and the fifth mode of the stocker apparatus 130, and when a failure occurs in any one of the first lamp 330a and the second lamp 330b, the other lamp may display any of the first mode to the fifth mode of the stocker apparatus 130.

Alternately, the first lamp 330a indicates the fourth mode and the fifth mode of the stocker apparatus 130, the second lamp 330b indicates the first mode to the third mode of the stocker apparatus 130, and when a failure occurs in any one of the first lamp 330a and the second lamp 330b, the other lamp may display any of the first mode to the fifth mode of the stocker apparatus 130.

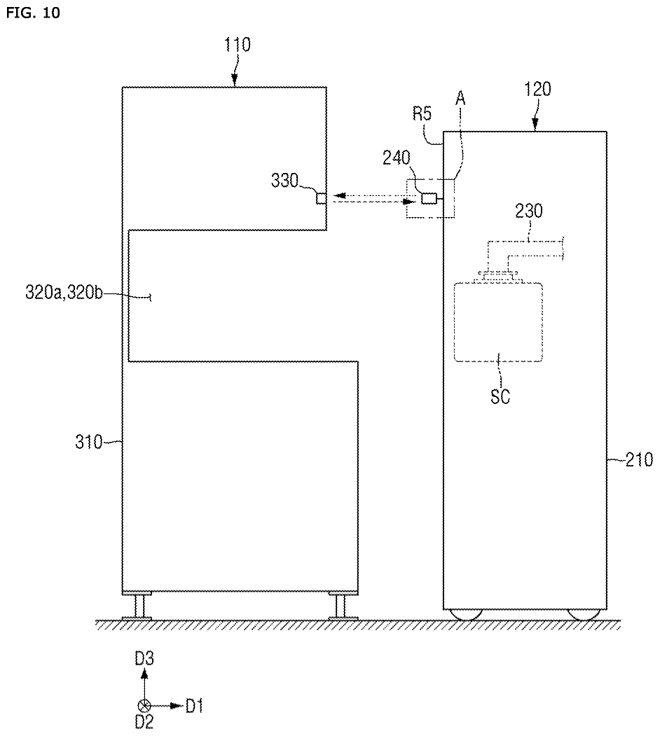

Referring to FIG. 10, the lamp 330 may be disposed at a higher level than the first opening 320a and the second opening 320b, but may be disposed at a lower level than the first opening 320a and the second opening 320b. The lamp sensing module 240 may be fixed on the first frame 210 or disposed inside the first frame 210, but the present disclosure is not limited thereto. For example, the lamp sensing module 240 may be provided on the transfer robot 120 and may be rotatable in consideration of the position of the lamp 330.

The lamp 330 of the manual port 110 may indicate the state of the stocker apparatus 130, and the position or the size of the lamp 330 on the manual port 110 may be different for different models. In addition, even in the case that the transfer robot 120 stops in front of the manual port 110 to load or unload the container SC, a distance difference between the transfer robot 120 and the manual port 110 may vary. Therefore, a position, angle, direction, range, and the like of the lamp sensing module 240 may be set and adjusted so that the lamp 330 may be recognized.

For example, a sensing range of the lamp sensing module 240 may be wider than a width of the manual port 110. For example, the sensing range of the lamp sensing module 240 may be greater than a width of the manual port 110 in the second direction D2. Alternatively, the sensing range of the lamp sensing module 240 may be wider than a height of the manual port 110, that is, the height of the manual port 110 in the third direction D3. Alternatively, the sensing range of the lamp sensing module 240 may be wider than the width of the manual port 110 and the height of the manual port 110. That is, the sensing range of the lamp sensing module 240 in the second direction D2 may be greater than the width of the manual port 110, and the sensing range of the lamp sensing module 240 in the third direction D3 may be greater than the height of the manual port 110. When the sensing range of the lamp sensing module 240 is formed as described above, the lamp 330 may be recognized by the transfer robot 120.

Referring to FIG. 10, the lamp sensing module 240 may be provided to be rotatable in the vertical direction, that is, the third direction D3 on a surface RS of the transfer robot 120, but the present disclosure is not limited thereto. The lamp sensing module 240 may be provided to be rotatable in the horizontal direction, that is, in the second direction D2 on the surface RS of the transfer robot 120. Alternatively, the lamp sensing module 240 may be provided to be rotatable in a diagonal direction on the surface RS of the transfer robot 120. FIG. 10 is an exemplary view illustrating a lamp sensing module of a transfer robot.

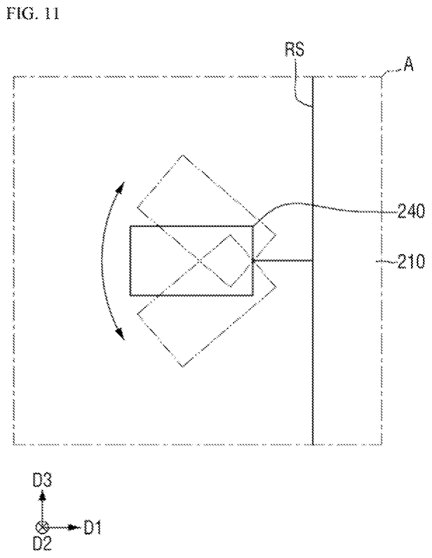

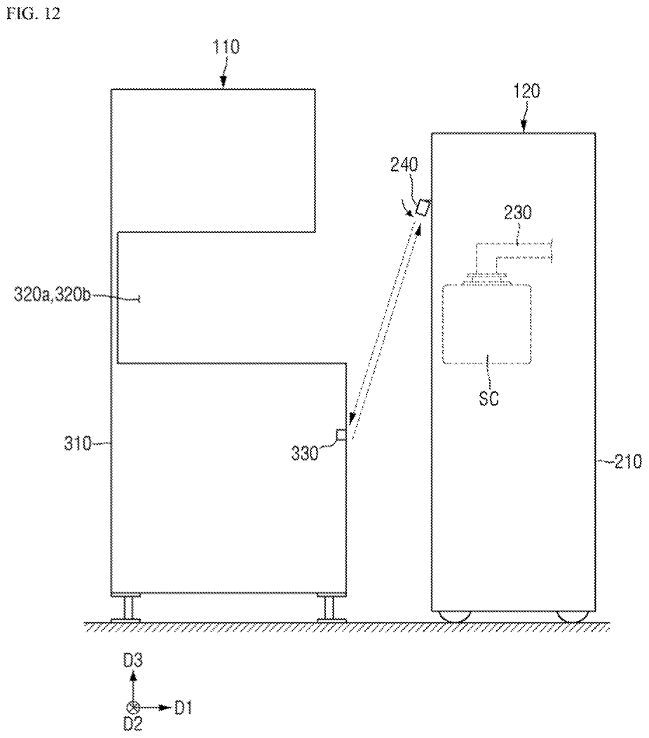

FIG. 11 is a first exemplary view illustrating a rotational motion of the lamp sensing module. In addition, FIG. 12 is a second exemplary view illustrating a rotational motion of the lamp sensing module.

Referring to FIG. 11, when the lamp sensing module 240 is disposed above the robot arm 230 of the transfer robot 120 and the lamp 330 may be disposed above the first lamp 330a and the second lamp 330b of the manual port 110, the lamp sensing module 240 may sense the lamp 330 in a state that the lamp sensing module 240 is oriented toward the horizontal direction without a separate rotation. Even in the case that the lamp sensing module 240 is disposed below the robot arm 230 of the transfer robot 120 and the lamp 330 is disposed below the first lamp 330a and the second lamp 330b of the manual port 110, the lamp sensing module 240 may operate in a manner described as above to sense the lamp 330.

Referring to FIG. 12, when the lamp sensing module 240 is disposed above the robot arm 230 of the transfer robot 120 and the lamp 330 is disposed below the first lamp 330a and the second lamp 330b of the manual port 110, the lamp sensing module 240 may rotate to be oriented toward a lower portion of the front surface of the manual port 110 and sense the lamp 330. Even in the case that the lamp sensing module 240 is disposed below the robot arm 230 of the transfer robot 120 and the lamp 330 is disposed above the first lamp 330a and the second lamp 330b of the manual port 110, the lamp sensing module 240 may operate in a manner described as above to sense the lamp 330.

When the lamp sensing module 240 is disposed above the robot arm 230 of the transfer robot 120 and the lamp 330 is disposed below the first lamp 330a and the second lamp 330b of the manual port 110, the sensing range of the lamp sensing module 240 may be limited by the robot arm 230. In addition, even in the case that the lamp sensing module 240 is disposed below the robot arm 230 of the transfer robot 120 and the lamp 330 is disposed above the first lamp 330a and the second lamp 330b of the manual port 110, such a phenomenon may occur.

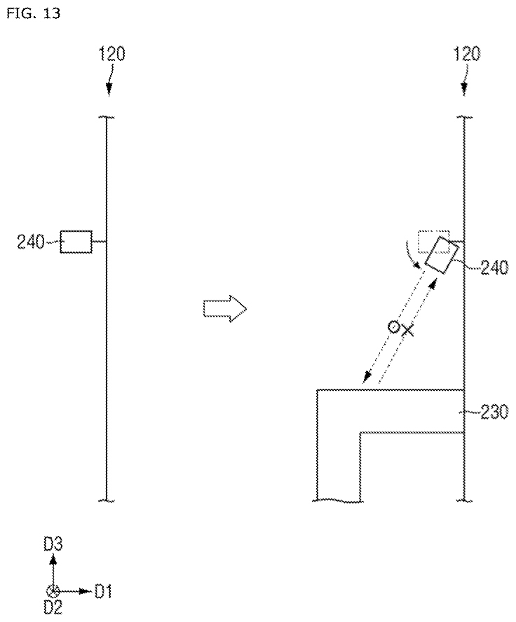

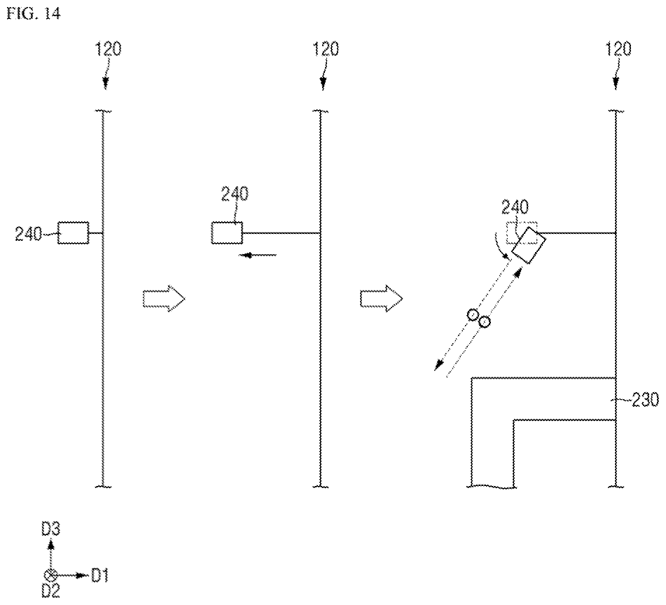

The lamp sensing module 240 may be perform a straight motion along with a rotational motion in consideration of the above aspects. FIG. 13 is a first exemplary view illustrating a rotational motion and a straight motion of a lamp sensing module. In addition, FIG. 14 is a second exemplary view illustrating a rotational motion and a straight motion of the lamp sensing module. In FIG. 13 and FIG. 14, a case that the lamp sensing module 240 is disposed above the front surface of the transfer robot 120 and the lamp 330 is disposed below the front surface of the manual port 110 will be described as an example.

Referring to FIG. 13, when the lamp sensing module 240 performs a rotational motion without a straight motion, a signal S1 output by the lamp sensing module 240 may be blocked by the robot arm 230. In this case, the lamp sensing module 240 may not sense the lamp 330.

Referring to FIG. 14, when the lamp sensing module 240 performs a rotational motion after performing a straight motion, the signal S1 output by the lamp sensing module 240 may not be blocked by the robot arm 230. In this case, the lamp sensing module 240 may sense the lamp 330. The straight motion may be an extension away from the surface of the transfer robot 120 along the first direction D1 and more particularly, in direction opposite to the first direction D1.

FIG. 14 shows that the lamp sensing module 240 may perform a straight motion along the first direction D1, but the present disclosure is not limited thereto. For example, the lamp sensing module 240 may move in a straight motion along the first direction D1, in a straight motion along the second direction D2, or in a straight motion along the third direction D3.

For example, to avoid the signal S1 output by the lamp sensing module 240 from being blocked by the robot arm 230, the lamp sensing module 240 may move in one or more direction. The lamp sensing module 240 may move in a direction along the first direction D1, the second direction D2, or the third direction D3. Alternatively, the lamp sensing module 240 may move along any two directions of the first direction D1, the second direction D2, or the third direction D3. Alternatively, the lamp sensing module 240 may move along each of the first direction D1, the second direction D2, and the third direction D3.

The robot arm 230 may be positioned inside the first frame 210, and may be positioned inside the first frame 210 in the case that the transfer robot 120 moves to transport the container SC to a destination. The robot arm 230 may extend from inside of the first frame 210 to the outside of the first frame 210 when the robot arm 230 arrives at the destination and transfers the container SC to the manual port 110.

The present disclosure is not limited to examples provided herein, and the robot arm 230 may extend to the outside of the first frame 210 while gripping the container SC. The function of the lamp sensing module 240 described with reference to FIG. 13 and FIG. 14 may be applied to this case.

The lamp sensing module 240 may be connected to one or more motors for performing the straight motion(s) and the rotational motion(s) of the lamp sensing module 240, but the present disclosure is not limited thereto. The lamp sensing module 240 may be connected to one or more hydraulic cylinders, or the like. The lamp sensing module 240 may be connected to one or more motors and one or more hydraulic cylinders. The transfer robot 120 may include at least one of the motor or the hydraulic cylinder in the first frame 210, but the present disclosure is not limited thereto, and the motor or the hydraulic cylinder may be provided separately from the transfer robot 120.

The lamp sensing module 240 may sense the lamp 330 installed in the manual port 110 in various ways in accordance with an embodiment. For example, the lamp sensing module 240 may sense the lamp 330 installed in the manual port 110 by using a camera sensor. As another example, the lamp sensing module 240 may sense the lamp 330 installed in the manual port 110 by using an optical sensor.

The container sensing module 220 and the lamp sensing module 240 may be provided as a same type of sensor in the transfer robot 120. For example, the container sensing module 220 and the lamp sensing module 240 may be provided as a vision sensor. In this case, one vision sensor may perform both a function of the container sensing module 220 and a function of the lamp sensing module 240, but the present disclosure is not limited thereto. Separate vision sensors may perform the function of the container sensing module 220 and the function of the lamp sensing module 240.

The container sensing module 220 and the lamp sensing module 240 may be provided as different types of sensors in the transfer robot 120. For example, the container sensing module 220 may be provided as a camera sensor, and the lamp sensing module 240 may be provided as an optical sensor. Alternatively, the container sensing module 220 may be provided as an optical sensor, and the lamp sensing module 240 may be provided as a camera sensor. The optical sensor may device for detecting visible or infrared light. The camera sensor may be a device for capturing an image.

Although not shown in the drawings, in the same manner as the case of the container sensing module 220, the lamp sensing module 240 may be disposed at a higher level than the robot arm 230 of the first frame 210. Alternatively, the lamp sensing module 240 may be disposed at a lower level than the robot arm 230 of the first frame 210, but the present disclosure is not limited thereto. The lamp sensing module 240 may be disposed at the same level as the robot arm 230 of the first frame 210.

In the same manner as the case of the lamp sensing module 240, the position, angle, direction, and range of the container sensing module 220 may be set and adjusted to recognize a FOUP in all cases. For example, the container sensing module 220 may be rotatable. The case that the lamp sensing module 240 is rotatable has been described herein, and may be applied to the container sensing module 220. In addition, the container sensing module 220 may move or rotate. The container sensing module 220 may move in a straight motion in one or more of the first direction D1, the second direction D2, or the third direction D3. The container sensing module 220 may rotate in the first direction D1, the second direction D2, or the third direction D3. The lamp sensing module 240 may perform the straight motion and the rotational motion as described herein, and may be applied to the container sensing module 220.

Referring again to FIG. 2 and FIG. 3, the electric power source 250 may provide power to one or more of the components of the transfer robot 120. The electric power source 250 may provide power to one or more of the container sensing module 220, the robot arm 230, the lamp sensing module 240, or the main control module 260.

The main control module 260 may control the overall operation of one or more components of the transfer robot 120. The main control module 260 may control the overall operation of one or more of the container sensing module 220, the robot arm 230, the lamp sensing module 240, or the electric power source 250.

Hereinafter, a container sensing method will be described in connection with the transfer robot 120 including the sensing module 420 (see FIG. 3) will be described as an example, but the present disclosure is not limited thereto. For example, the same method may be applied to the case that the transfer robot 120 includes the container sensing module 220 and the lamp sensing module 240 as separate components.

The transfer robot 120 may stop at a designated position to access the manual port 110. The designated position may be set based on a capability of the robot arm 230, a distance to the manual port 110, and a posture of the manual port 110. For example, the capability of the robot arm 230 may be related to an extendable distance of the robot arm 230. The controller 140 may determine whether the deviation between the designated position and the stopped position exceeds a predetermined reference, based on the sensing result of the sensing module 420. When a deviation between the designated position and a stopped position exceeds a predetermined reference (for example, ±20 mm of position error) in accordance with a determination result of the controller 140, the transfer robot 120 may reposition at the designated position. The controller 140 may redetermine whether the deviation between the designated position and the stopped position exceeds the predetermined reference, based on the sensing result of the sensing module 420. The predetermined reference may ensure that a field of view (FOV) of the sensing module 420, which is based on the stopped position of the transfer robot 120, includes the lamp 330 of the manual port 110.

The transfer robot 120 may sense the lamp 330 of the manual port 110 by using the sensing module 420 when the stop is completed at the designated position. In this case, the controller 140 may determine whether the light output from the lamp 330 has predetermined illuminance or more.

In addition, the controller 140 may determine whether the stocker apparatus 130 may load or unload the container, based on whether the lamp 330 is turned on or not. For example, when it is determined that the lamp 330 is turned on, the controller 140 may determine that the stocker apparatus 130 is in a state prepared for loading or unloading the container.

When it is determined that the light output from the lamp 330 is detected to be greater than or equal to predetermined illuminance, the controller 140 may determine whether the stocker apparatus 130 is prepared for loading or unloading the container, based on whether the lamp 330 is turned on or not. The transfer robot 120 may sense the lamp 330 at a predetermined time interval a plurality of times, and the controller 140 may determine that the stocker apparatus 130 is in a state prepared for loading or unloading when it is determined that the lamp 330 is turned on as a result of sensing of the lamp 330 a plurality of times.

When it is determined that the lamp 330 is flashing or the lamp 330 is turned off, the controller 140 may determine that the stocker apparatus 130 is not in a state prepared for loading or unloading. For example, when the work of the stocker apparatus 130 is in progress, the lamp 330 may be flashing, and when an error has occurred in the work of the stocker apparatus 130, the lamp 330 may be turned off.

When it is determined by the controller 140 that the stocker apparatus 130 is in a state prepared for loading or unloading, the sensing module 420 may sense whether the container SC is present in the first opening 320a or the second opening 320b of the manual port 110. In addition, the controller 140 may determine whether the container SC exists in the first opening 320a or the second opening 320b of the manual port 110, based on the sensing result of the sensing module 420.

For example, when the container SC is a FOUP and the sensing module 420 includes a vision sensor, and when at least a portion of the FOUP is detected in image information obtained as a result of sensing of the sensing module 420, the controller 140 may determine that the container SC is present in the first opening 320a or the second opening 320b of the manual port 110. The portion of the FOUP detected by the sensing module 420 may be a flange of the FOUP. The flange may be detected by image recognition software or an identifying characteristic, for example, a unique color. In this case, the flange of the FOUP may be a portion of the FOUP which may be gripped by the robot arm 230.

The controller 140 may determine that the container SC is not present in the first opening 320a or the second opening 320b of the manual port 110 when the flange of the FOUP is not detected in the image information obtained as a result of sensing of the sensing module 420.

The sensing module 420 may sense whether the container SC is present in the first opening 320a of the manual port 110. The controller 140 may determine whether the container SC is present in the first opening 320a of the manual port 110, based on the sensing result of the sensing module 420.

The first opening 320a may be used as an input port of the stocker apparatus 130. That is, the first opening 320a may be used as a port for transferring the container SC to the stocker apparatus 130. The first opening 320a may be clear (e.g., of another container) when the transfer robot 120 transfers the container SC to the stocker apparatus 130. Therefore, when it is determined that the first opening 320a is clear by the controller 140, the transfer robot 120 may carry the container SC into the first opening 320a under the control of the controller 140.

When it is determined that another container is present in the first opening 320a, the transfer robot 120 may enter a standby state without transferring the container SC to the first opening 320a. The controller 140 may command the stocker apparatus 130 to process any container in the first opening 320a while the transfer robot 120 is in the standby state. Once the stocker apparatus 130 clears the first opening 320a, the transfer robot 120 may carry the container SC into the first opening 320a.

The sensing module 420 may sense whether the container SC is present in the second opening 320b of the manual port 110. The controller 140 may determine whether the container SC exists in the second opening 320b of the manual port 110, based on the sensing result of the sensing module 420.

The second opening 320b may be used as an output port of the stocker apparatus 130. That is, the second opening 320b may be used as a port for receiving the container SC from the stocker apparatus 130. When the transfer robot 120 receives the container SC from the stocker apparatus 130, the container SC should be present in the second opening 320b. Therefore, when it is determined that the container SC is present in the second opening 320b by the controller 140, the transfer robot 120 takes the container SC out of the second opening 320b under the control of the controller 140.

In a case that it is determined that the container SC is not present in the second opening 320b, the transfer robot 120 may enter the standby state. The transfer robot 120 may remain in the standby state until the container SC may be carried into the second opening 320b by the stocker apparatus 130. The controller 140 may command the stocker apparatus 130 to transfer the container, which is to be taken out, to the second opening 320b while the transfer robot 120 is in the standby state. One the stocker apparatus 130 carries the container SC into the second opening 320b, the transfer robot 120 may take the container SC out of the second opening 320b.

As described herein, the transfer robot 120 and the stocker system 100 including the same have been described with reference to FIGS. 1 to 14. When a container is transported to a destination, an OHT moving on a pre-installed rail may be used for transportation of the container. However, due to the lack of capacity of the OHT, transfer robot may need to carry the container to the destination.

In the case where the transfer robot is used to carry the container, an interface loader may be installed in front of a manual port of a stocker, and the transfer robot may exchange information with the interface loader to exchange the container.

The transfer robot 120 may have a dimension to fit in small spaces within the semiconductor manufacturing factory. Further, the transfer robot 120 may eliminate a need for a worker to be present during an exchange of containers, and spaces within the semiconductor manufacturing factory may be reduced in size. For example, the semiconductor manufacturing factory may be configured to have additional equipment.

The transfer robot may provide a container to and remove a container from the manual port, and a working time needed to perform the loading and unloading operation of the container may be reduced.

A state of the interface loader may be sensed by the transfer robot. The transfer robot may determine whether the interface loader has a container present in the manual port and determine whether the container may be loaded and unloaded. Thus, no communication may be needed between the interface loader and the transfer robot. The transfer robot may quickly determine the state of the manual port and information as to whether the container is present in the manual port.

Therefore, there is a need for a manipulator integrated mobile robot capable of directly loading and unloading the container into and from the manual port without a need for communicating with the interface loader.

In the stocker system 100 according to an embodiment, the transfer robot 120 may directly recognize the state of the manual port 110 or the state of the stocker apparatus 130, and may directly recognize whether the container SC is present in the manual port 110. In addition, the transfer robot 120 may directly recognize whether the manual port 110 is ready to load and unload the container SC. For example, the transfer robot 120 may recognize the state of the manual port 110, the state of the stocker apparatus 130, whether the container SC is present in the manual port 110, and whether the manual port 110 is ready to load and unload the container SC, by using the vision sensor.

According to an embodiment, a separate infrastructure (for example, interface loader) in front of the manual port 110 of the stocker apparatus 130 may be omitted, and the time to complete the loading and unloading operation of the container SC may be shortened. In addition, a passage width in a bay may be reduced or eliminated as the interface loader may not impinge on the passage width. In addition, automatic loading and unloading of the container SC may be possible in different types of manual ports 110 without installation of the interface loader.

The transfer robot 120 may be provided as a system for sensing a facility state of the stocker apparatus 130 and a loading operation and an unloading operation of the container SC may be based on visual recognition performed by the transfer robot 120. The transfer robot 120 and the stocker system 100 including the same may be applied to construction of a logistics automation service in a semiconductor manufacturing factory.

The transfer robot 120 may sense a loading work state and an unloading work state of the container SC of the stocker apparatus 130. The transfer robot 120 may sense the loading work state and the unloading work state of the container SC of the stocker apparatus 130 by using the lamp sensing module 240. The controller 140 may communicate with the lamp sensing module 240 of the transfer robot 120 to determine the loading work state and the unloading work state of the container SC of the stocker apparatus 130 as the first mode in which the stocker apparatus 130 loads the container SC and the second mode in which the stocker apparatus 130 unloads the container SC.

The transfer robot 120 may sense a current state of the stocker apparatus 130. The transfer robot 120 may sense the current state of the stocker apparatus 130 by using the lamp sensing module 240. The controller 140 may communicate with the lamp sensing module 240 of the transfer robot 120 to determine the current state of the stocker apparatus 130 as the fourth mode in which the stocker apparatus 130 may load and unload the container SC, the fifth mode in which the stocker apparatus 130 may not load and unload the container SC, and the like.

Exemplary embodiments of the present disclosure have been described hereinabove with reference to the accompanying drawings, but the present disclosure is not limited to exemplary embodiments, and may be implemented in various different forms, and one of ordinary skill in the art to which the present disclosure pertains may understand that the present disclosure may be implemented in other specific forms without changing the technical concept or features of the present disclosure. Therefore, it is to be understood that exemplary embodiments described above are illustrative rather than being restrictive in all aspects.

What is claimed is:

1. A stocker system comprising:
a stocker apparatus;
a transfer robot including a sensing module and a robot arm;
a manual port configured to operate as an interface, which transfers a container, between the stocker apparatus and the transfer robot; and
a controller in communication with the transfer robot,
wherein the controller communicates with the sensing module to determine that the container is transferrable by the robot arm between the manual port of the stocker apparatus and the transfer robot.

2. The stocker system of claim 1, wherein the manual port includes a lamp for indicating a state of the stocker apparatus, and
the controller determines that the container is transferrable using a result obtained by the sensing module sensing of the lamp.

3. The stocker system of claim 2, wherein the sensing module senses an indication of the lamp.

4. The stocker system of claim 2, wherein the controller determines the container is transferrable depending on an illuminance of light output from the lamp.

5. The stocker system of claim 1, wherein the sensing module senses a position of the transfer robot relative to a designated position.

6. The stocker system of claim 1, wherein the sensing module determines a deviation between a designated position and the position of the transfer robot.

7. The stocker system of claim 1, wherein the controller determines that the stocker apparatus is prepared to load or unload the container and determines that the container is present in the manual port.

8. The stocker system of claim 1, wherein the transfer robot loads the container into the stocker apparatus or unloads the container from the stocker apparatus depending on a determination that the container is present in the manual port.

9. The stocker system of claim 1, wherein the determination that the container is transferrable by the robot arm between the manual port of the stocker apparatus and the transfer robot is performed at a predetermined time interval.

10. The stocker system of claim 1, wherein the sensing module includes a vision sensor.

11. The stocker system of claim 1, wherein the manual port includes a first opening and a second opening, the first opening is used to load the container to the stocker apparatus, and the second opening is used to unload the container from the stocker apparatus.

12. The stocker system of claim 1, wherein the robot arm is disposed in a frame of the transfer robot, and the robot arm is extendable to outside of the frame.

13. The stocker system of claim 1, wherein a sensing range of the sensing module is at least one of wider than a width of the manual port or greater than a height of the manual port.

14. The stocker system of claim 2, wherein the sensing module senses the lamp, and
the controller determines the state of the stocker apparatus based on a result obtained by the sensing of the lamp, and determines that the stocker apparatus is prepared for a transfer of the container.

15. The stocker system of claim 2, wherein the sensing module senses that the lamp is one of turned on, flashing, or turned off, and
the state of the stocker apparatus is one of the container is loaded in the stocker apparatus, the container is unloaded from the stocker apparatus, or the stocker apparatus is not available for transfer of the container.

16. The stocker system of claim 1, wherein the sensing module is rotatable on a surface of the transfer robot.

17. The stocker system of claim 1, wherein the sensing module is extendable from a surface of the transfer robot.

18. A transfer robot operating in a semiconductor manufacturing factory, the transfer robot comprising:
a frame;
a robot arm disposed in the frame and extendable to outside of the frame; and
a lamp sensing module outputting a signal indicative of whether a stocker apparatus is prepared to transfer a container.

19. The transfer robot of claim 18, wherein the sensing module senses that a lamp of the stocker apparatus is turned on, flashing, or turned off, or senses a color displayed by the lamp of the stocker apparatus, and senses a position of the transfer robot relative to a designated position.

20. A stocker system comprising:
a stocker apparatus storing a container in which a plurality of substrates are accommodated;
a transfer robot including a sensing module and a robot arm;
a manual port configured to operate as an interface, which transfers the container, between the stocker apparatus and the transfer robot; and
a controller controlling the stocker apparatus and the transfer robot,
wherein the controller communicates with the sensing module to determine a state of the stocker apparatus,
the manual port includes a lamp indicating the state of the stocker apparatus, the sensing module senses the lamp, and
the robot arm transfers the container between the manual port of the stocker apparatus and the transfer robot depending on the state of the stocker apparatus.
